(19) United States
(12) Patent Application Publication
(10) Pub. No.: US 2025/0191845 A1
(43) Pub. Date: Jun. 12, 2025

(54) CHIP ELECTRONIC COMPONENT

(71) Applicant: Murata Manufacturing Co., Ltd., Nagaokakyo-shi (JP)

(72) Inventors: Tatsunori YASUDA, Nagaokakyo-shi (JP); Kazuki KUROKAWA, Nagaokakyo-shi (JP); Akira OONO, Nagaokakyo-shi (JP)

(21) Appl. No.: 19/055,828

(22) Filed: Feb. 18, 2025

Related U.S. Application Data
(63) Continuation of application No. PCT/JP2023/029583, filed on Aug. 16, 2023.

(30) Foreign Application Priority Data
Oct. 3, 2022 (JP) 2022-159642

(51) Int. Cl. H01G 4/30; H05K 1/02; H05K 1/18

(52) U.S. Cl. CPC H01G 4/30; H05K 1/0271; H05K 1/181; H05K 2201/10015; H05K 2201/1031; H05K 2201/10568

(57) ABSTRACT

A chip electronic component includes a multilayer ceramic capacitor and spacers. The multilayer ceramic capacitor includes a multilayer body including inner electrode layers and dielectric layers that are alternately arranged, and outer electrodes. The multilayer body includes capacitor principal surfaces opposite to each other in a lamination direction, capacitor side surfaces opposite to each other in a width direction, and capacitor end surfaces opposite to each other in a length direction. Outer electrodes are provided on respective ones of capacitor end surfaces. The spacers are provided at both ends of one of the capacitor principal surfaces adjacent to a mounting board for the multilayer ceramic capacitor. Each spacer includes spacer principal surfaces opposite to each other in the lamination direction. At least one recess is provided in a surface of one of the spacer principal surfaces adjacent to the mounting board.

### CROSS REFERENCE TO RELATED APPLICATIONS

This application claims the benefit of priority to Japanese Patent Application No. 2022-159642 filed on Oct. 3, 2022 and is a Continuation Application of PCT Application No. PCT/JP2023/029583 filed on Aug. 16, 2023. The entire contents of each application are hereby incorporated herein by reference.

### BACKGROUND OF THE INVENTION

### 1. Field of the Invention

The present invention relates to chip electronic components.

### 2. Description of the Related Art

A multilayer ceramic capacitor includes a multilayer body and outer electrodes provided on both end surfaces of the multilayer body in a longitudinal direction of the multilayer body. The multilayer body includes an inner layer portion in which dielectric layers and inner electrodes are alternately stacked. When a voltage is applied to the multilayer ceramic capacitor, the dielectric layers are polarized. This may cause the multilayer ceramic capacitor to vibrate in the polarization direction. In such a case, the vibration may be transmitted to a mounting board, forming cracks in the mounting board. Therefore, the transmission of the vibration to the mounting board has been reduced by arranging spacers on a surface of the multilayer ceramic capacitor that is adjacent to the mounting surface to form a chip electronic component, and absorbing the vibration with the spacers (see International Publication No. 2015/098990).

### SUMMARY OF THE INVENTION

However, when, for example, the dielectric layers contain components having a high dielectric constant, a greater vibration occurs. Therefore, when the joining strength between the mounting board and the spacer is weak, there is a possibility that the spacers will become separated from the mounting board.

Example embodiments of the present invention provide chip electronic components in each of which spacers are not easily separated from a mounting board.

An example embodiment of the present invention provides a chip electronic component including a multilayer ceramic capacitor and spacers. The multilayer ceramic capacitor includes a multilayer body including a plurality of inner electrode layers and a plurality of inner dielectric layers that are alternately arranged, and outer electrodes. The multilayer body includes capacitor principal surfaces opposite to each other in a lamination direction, capacitor side surfaces opposite to each other in a width direction that crosses the lamination direction, and capacitor end surfaces opposite to each other in a length direction that crosses the lamination direction and the width direction. The outer electrodes are provided on respective ones of the capacitor end surfaces. The spacers are provided at both ends of one of the capacitor principal surfaces in the length direction, the one of the capacitor principal surfaces being adjacent to a mounting board for the multilayer ceramic capacitor. Each of the spacers includes spacer principal surfaces opposite to each other in the lamination direction, and at least one recess is provided in a surface of one of the spacer principal surfaces that is adjacent to the mounting board.

Example embodiments of the present invention provide chip electronic components in each of which spacers are not easily separated from a mounting board.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic perspective view of a chip electronic component 1 according to an example embodiment of the present invention.

FIG. 2 is a partial sectional view of the chip electronic component 1 taken along line II-II in FIG. 1.

FIG. 3 is a sectional view of the chip electronic component 1 taken along line III-III in FIG. 1.

FIG. 4 illustrates a spacer 10 oriented such that a second spacer principal surface AS2 faces upward.

FIG. 5 is a flowchart of a method for manufacturing the chip electronic component 1.

FIG. 6 a partial sectional view of a modification of the chip electronic component 1.

### DETAILED DESCRIPTION OF THE EXAMPLE EMBODIMENTS

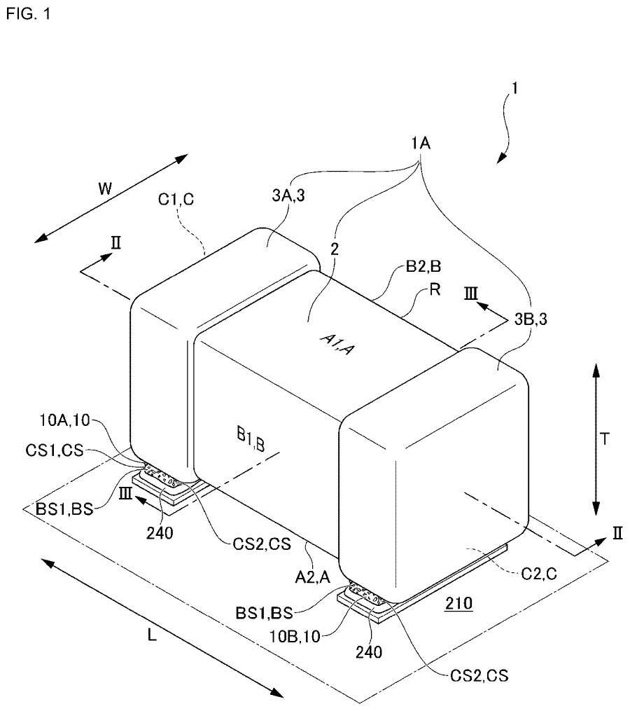

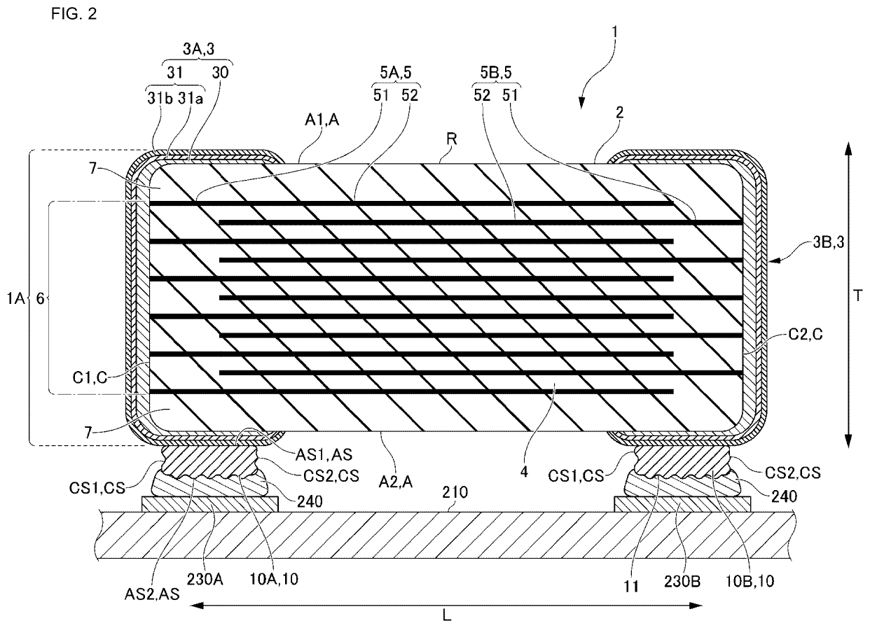

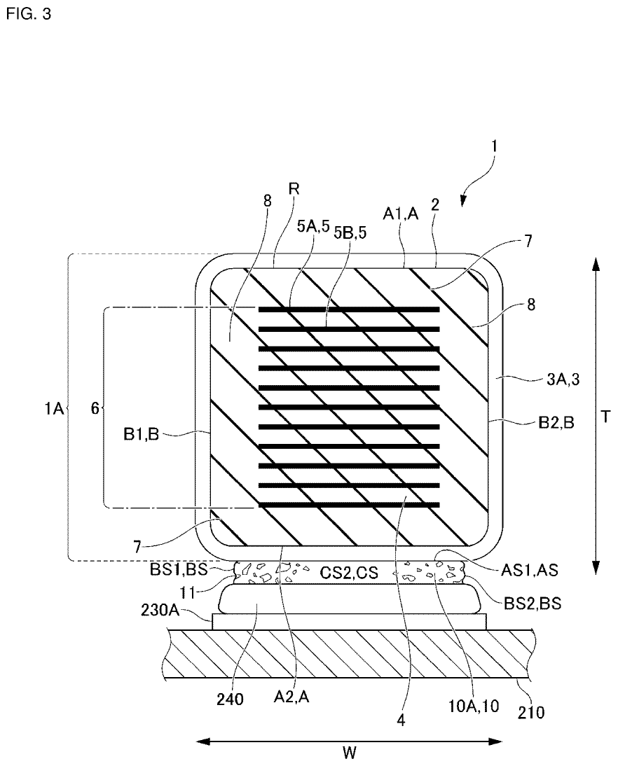

Example embodiments of the present invention will now be described. FIG. 1 is a schematic perspective view of a chip electronic component 1 according to an example embodiment. FIG. 2 is a partial sectional view of the chip electronic component 1 taken along line II-II in FIG. 1. FIG. 3 is a sectional view of the chip electronic component 1 taken along line III-III in FIG. 1. FIGS. 1, 2, and 3 illustrate the chip electronic component 1 joined to a mounting board 210.

The chip electronic component 1 includes a multilayer ceramic capacitor 1A and spacers 10 attached to the multilayer ceramic capacitor 1A. The multilayer ceramic capacitor 1A includes a substantially rectangular-parallelepiped-shaped multilayer body 2 and a pair of outer electrodes 3 provided on both ends of the multilayer body 2. The multilayer body 2 includes an inner layer portion 6 including a plurality of dielectric layers 4 and a plurality of inner electrode layers 5.

In the following description, the orientation of the chip electronic component 1 is described using the following terms. That is, the direction in which the outer electrodes 3 are arranged is referred to as a length direction L. The direction in which the dielectric layers 4 and the inner electrode layers 5 are laminated is referred to as a lamination direction T. The direction crossing both the length direction L and the lamination direction T is referred to as a width direction W. In the present example embodiment, the width direction W is orthogonal to both the length direction L and the lamination direction T.

Of the six outer surfaces of the multilayer body 2, a pair of outer surfaces opposite to each other in the lamination direction T is referred to as a first capacitor principal surface A1 and a second capacitor principal surface A2, a pair of outer surfaces opposite to each other in the width direction W is referred to as a first capacitor side surface B1 and a second capacitor side surface B2, and a pair of outer surfaces opposite to each other in the length direction L is referred to as a first capacitor end surface C1 and a second capacitor end surface C2.

The first capacitor principal surface A1 and the second capacitor principal surface A2 are collectively referred to as capacitor principal surfaces A when distinction therebetween is not particularly necessary. The first capacitor side surface B1 and the second capacitor side surface B2 are collectively referred to as capacitor side surfaces B when distinction therebetween is not particularly necessary. The first capacitor end surface C1 and the second capacitor end surface C2 are collectively referred to as capacitor end surfaces C when distinction therebetween is not particularly necessary.

The multilayer body 2 includes the inner layer portion 6, outer layer portions 7 provided on the sides of the inner layer portion 6 adjacent to the capacitor principal surfaces A, and side gap portions 8. The multilayer body 2 preferably has rounded ridge portions R. The ridge portions R include an intersection portion between two surfaces of the multilayer body 2, that is, between one capacitor principal surface A and one capacitor side surface B, one capacitor principal surface A and one capacitor end surface C, and/or one capacitor side surface B and one capacitor end surface C. The ridge portions R also include an intersection corner portion between one capacitor principal surface A, one capacitor side surface B, and one capacitor end surface C.

The inner layer portion 6 includes the dielectric layers 4 and the inner electrode layers 5 that are alternately laminated in the lamination direction T.

The dielectric layers 4 are made of a ceramic material. The ceramic material may be, for example, a dielectric ceramic containing BaTiO₃ as the main component. The ceramic material may contain at least one of secondary components including a Mn compound, a Fe compound, a Cr compound, a Co compound, and a nickel compound added to the main component.

The inner electrode layers 5 are preferably made of a metal material, such as nickel, Cu, Ag, Pd, a Ag—Pd alloy, or Au.

The inner electrode layers 5 include a plurality of first inner electrode layers 5A and a plurality of second inner electrode layers 5B. The first inner electrode layers 5A and the second inner electrode layers 5B are alternately arranged. The first inner electrode layers 5A and the second inner electrode layers 5B are collectively referred to as inner electrode layers 5 when distinction therebetween is not particularly necessary.

The inner electrode layers 5 include facing portions 52 and extending portions 51. The facing portions 52 are portions of the first inner electrode layers 5A and the second inner electrode layers 5B that face each other. The extending portions 51 are portions of the first inner electrode layers 5A and the second inner electrode layers 5B that do not face each other and that extend from the facing portions 52 toward one of the capacitor end surfaces C. The extending portions 51 include end portions that are exposed at the capacitor end surfaces C and electrically connected to the outer electrodes 3. The direction in which each extending portion 51 extends differs between the first inner electrode layers 5A and the second inner electrode layers 5B. The extending portions 51 extend alternately toward the first capacitor end surface C1 and the second capacitor end surface C2. The electric charge accumulates between the facing portions 52 of the first inner electrode layers 5A and the second inner electrode layers 5B that are adjacent to each other in the lamination direction T. Thus, the function of a capacitor is provided.

The outer layer portions 7 are arranged on the sides of the inner layer portion 6 adjacent to the capacitor principal surfaces A, and are made of the same material as the dielectric layers 4 of the inner layer portion 6.

The side gap portions 8 are provided on the sides of the inner layer portion 6 of the multilayer body 2 adjacent to the capacitor side surfaces B. The side gap portions 8 are made of the same material as the dielectric layers 4 and formed integrally with the dielectric layers 4.

The outer electrodes 3 are provided on the capacitor end surfaces C of the multilayer body 2. More specifically, a first outer electrode 3A is provided on the first capacitor end surface C1, and a second outer electrode 3B is provided on the second capacitor end surface C2. The outer electrodes 3 cover not only the capacitor end surfaces C but also portions of the capacitor principal surfaces A and the capacitor side surfaces B adjacent to the capacitor end surfaces C. Each outer electrode 3 includes a base electrode layer 30 and a plating layer 31 provided on the outer periphery of the base electrode layer 30.

The base electrode layer 30 is electrically connected to the end portions of the extending portions 51 of the inner electrode layers 5 exposed at each capacitor end surface C. In the present example embodiment, the base electrode layer 30 is, for example, a so-called baked electrode formed by firing a conductive paste including a conductive metal, such as copper, nickel, silver, palladium, a silver-palladium alloy, or gold. The baked electrode includes a glass component and a metal. The glass component includes at least one selected from a group including B, Si, Ba, Mg, Al, and Li. The baked electrode is formed by applying the conductive paste including glass and metal to the multilayer body 2 and baking the conductive paste. The conductive paste may be fired together with the inner electrode layers 5 and the dielectric layers 4 or be baked after the inner electrode layers 5 are fired. When the conductive paste is fired together with the inner electrode layers 5 and the dielectric layers 4, the baked electrode is preferably formed by adding a dielectric material instead of the glass component.

The plating layer 31 includes a Ni plating layer 31a provided on the outer periphery of the base electrode layer 30 to cover the base electrode layer 30, and a Sn plating layer 31b provided on the outer periphery of the Ni plating layer 31a to cover the Ni plating layer 31a. The Ni plating layer 31a prevents the base electrode layer 30 from being corroded by solder when the ceramic electronic component is mounted. The Sn plating layer 31b facilitates the mounting of the multilayer ceramic capacitor 1A by improving solderability. The Ni plating layer 31a includes plating made of nickel or an alloy including nickel. The Sn plating layer 31b includes plating made of Sn or an alloy including Sn. The plating layer 31 may include at least one selected from a group including Cu, Ni, Sn, Ag, Pd, a Ag—Pd alloy, and Au, for example, in addition to the above-described metals.

The spacers 10 are a pair of spacers including a first spacer 10A and a second spacer 10B. The first spacer 10A and the second spacer 10B are collectively referred to as spacers 10 when distinction therebetween is not necessary. The first spacer 10A and the second spacer 10B are adjacent to the second capacitor principal surface A2 of the multilayer ceramic capacitor 1A. The first spacer 10A is at one end in the length direction L, and the second spacer 10B is at the other end in the length direction L. The first spacer 10A and the second spacer 10B have the same rectangular or substantially rectangular shape and are arranged to face each other with a certain distance therebetween.

Each spacer 10 is substantially rectangular-parallelepiped-shaped. Of the six outer surfaces of the spacer 10, a pair of outer surfaces opposite to each other in the lamination direction T is referred to as a first spacer principal surface AS1 and a second spacer principal surface AS2, a pair of outer surfaces opposite to each other in the width direction W is referred to as a first spacer side surface BS1 and a second spacer side surface BS2, and a pair of outer surfaces opposite to each other in the length direction L is referred to as a first spacer end surface CS1 and a second spacer end surface CS2.

The first spacer principal surface AS1 is a surface adjacent to the multilayer body 2, and the second spacer principal surface AS2 is a mounting surface joined to the mounting board 210.

The first spacer principal surface AS1 of the first spacer 10A is in contact with a surface of the first outer electrode provided on the first capacitor end surface C1 at a side adjacent to the second capacitor principal surface A2. The first spacer principal surface AS1 of the second spacer 10B is in contact with a surface of the second outer electrode provided on the second capacitor end surface C2 at a side adjacent to the second capacitor principal surface A2.

The shape of each spacer 10 in cross section orthogonal to the lamination direction T is a rectangular or substantially rectangular shape having short sides extending in the length direction L and long sides extending in the width direction W. The first spacer side surface BS1 and the second spacer side surface BS2 extend along the short sides of the spacer 10, and the first spacer end surface CS1 and the second spacer end surface CS2 extend along the long sides of the spacer 10.

The first spacer end surface CS1 of the first spacer 10A is adjacent to the first outer electrode 3A at a side adjacent to the first capacitor end surface C1, and the second spacer end surface CS2 of the second spacer 10B is adjacent to the second outer electrode 3B at a side adjacent to the second capacitor end surface C2.

The first spacer principal surface AS1 and the second spacer principal surface AS2 are collectively referred to as spacer principal surfaces AS when distinction therebetween is not particularly necessary. The first spacer side surface BS1 and the second spacer side surface BS2 are collectively referred to as spacer side surfaces BS when distinction therebetween is not particularly necessary. The first spacer end surface CS1 and the second spacer end surface CS2 are collectively referred to as spacer end surfaces CS when distinction therebetween is not particularly necessary.

The shape of each spacer 10 is not limited to the rectangular or substantially rectangular parallelepiped shape, and may be another hexahedral shape in which the area of the first spacer principal surface AS1 is greater than that of the second spacer principal surface AS2. It is not necessary that the spacer side surfaces BS and the spacer end surfaces CS be perpendicular to the second spacer principal surface AS2, which is the mounting surface. In addition, for example, the first spacer side surface BS1, the second spacer side surface BS2, the first spacer end surface CS1, and the second spacer end surface CS2 may be curved.

Each spacer 10 is made of a so-called high-temperature solder that includes an intermetallic compound including a high-melting-point metal and a low-melting-point metal as the main component. In this specification, to contain a substance as the main component means that the content of the substance is 50% or more. When the intermetallic compound is used as the main component, the reaction rate can be increased and the deformation can be reduced.

The high-melting-point metal includes at least one of Cu or Ni, and the low-melting-point metal includes Sn. When the intermetallic compound including the high-melting-point metal including at least one of Cu or Ni and the low-melting-point metal including Sn is contained as the main component, the melting point is such that melting does not occur at the soldering temperature, and the desired shape can be maintained during soldering. In particular, the intermetallic compound is preferably produced as a result of a reaction between Sn and a Cu—Ni alloy. The intermetallic compound may further include Ag as the high-melting-point metal.

Alternatively, each spacer 10 may be made of a conductive resin. The conductive resin includes a metal and a thermosetting resin. The spacer 10 made of a conductive resin is more flexible than, for example, a conductive layer including a plating film or fired conductive paste because the resin is included therein.

The metal included in the conductive resin may be Ag, Cu, or an alloy thereof. Metal particles having Ag-coated surfaces may be used. When metal particles having Ag-coated surfaces are used, the metal particles are preferably made of Cu or Ni. Alternatively, Cu subjected to an antioxidation treatment may also be used. The content of the metal in the conductive resin is preferably about 35 vol % or more and about 75 vol % or less of the overall volume of the conductive resin, for example. The metal included in the conductive resin may be in the form of, for example, spherical or flat particles, but a mixture of spherical metal particles and flat metal particles is preferably used. The average particle size of the metal included in the conductive resin is not particularly limited. The average particle size of the conductive fillers may be, for example, about 0.3 μm or more and about 10 μm or less. The metal included in the conductive resin mainly provides the conductivity of the conductive resin. More specifically, the conductive fillers are in contact with each other to provide conductive paths in the conductive resin.

The resin included in the conductive resin may be various known thermosetting resins, such as epoxy resins, phenolic resins, urethane resins, silicone resins, or polyimide resins. In particular, epoxy resins, which have high heat resistance, moisture resistance, and adhesiveness, are one of the most suitable resins. The content of the resin in the conductive resin is preferably about 25 vol % or more and about 65 vol % or less of the overall volume of the conductive resin, for example. The conductive resin preferably includes a solidifying agent in addition to the thermosetting resin. With regard to the solidifying agent, when an epoxy resin is used as the base resin, the solidifying agent for the epoxy resin may be various known compounds such as phenol-based, amine-based, acid anhydride-based, and imidazole-based compounds.

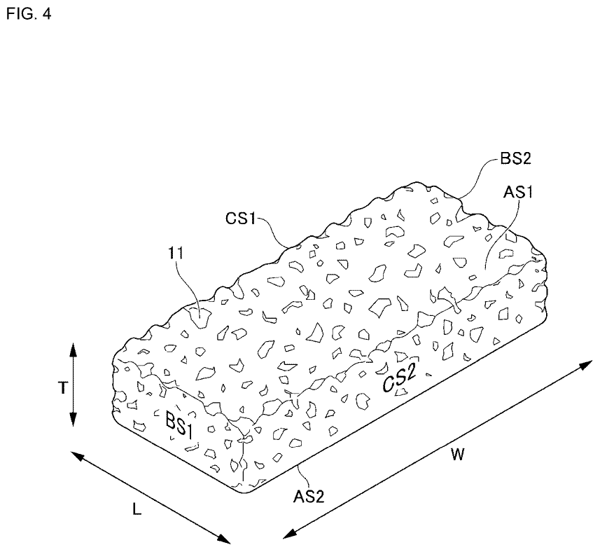

One or more recesses 11 may be provided in the surface of the second spacer principal surface AS2, which is the mounting surface, of each spacer 10. Plural recesses 11 may be provided. FIG. 4 illustrates the spacer 10 oriented such that the second spacer principal surface AS2 faces upward. In the present example embodiment, the recesses 11 are provided in the surface of the second spacer principal surface AS2. Therefore, when the chip electronic component 1 is mounted on the mounting board 210, solder 240 flows into the recesses 11 and exerts an anchoring effect that increases the fixing strength between the solder 240 and the spacer 10.

The total opening area of the recesses 11 is preferably about 25% or more and about 75% or less of the surface area of the second spacer principal surface AS2, for example.

The reason for this is as follows. When the total opening area of the recesses 11 is greater than about 75% of the area of the second spacer principal surface AS2, for example, a large portion of the solder 240 is trapped in the recesses 11, and the solder 240 cannot easily spread to the spacer end surfaces CS and the spacer side surfaces BS of the spacer 10. As a result, the joining strength between the spacer 10 and the mounting board 210 is reduced. When the total opening area of the recesses 11 is less than about 25% of the overall area of the second spacer principal surface AS2, for example, the joining area between the solder 240 and the spacer 10 is reduced, and a sufficient anchoring effect cannot be provided between the solder 240 and the spacer 10.

The total opening area of the recesses 11 in the spacer 10 is the sum of the areas of openings of the recesses 11 viewed from the second spacer principal surface AS2.

The second spacer principal surface AS2 of each spacer 10 is not flat, and includes projections and recesses. Here, a thickness of the spacer 10 is defined as the distance from the highest position on the second spacer principal surface AS2 of the spacer 10, that is, the vertices of the projections, to the first spacer principal surface AS1 in the lamination direction T. When the second spacer principal surface AS2 is brought into contact with a flat surface, the flat surface comes into contact with the vertices of the projections on the second spacer principal surface AS2. Portions spaced from that flat surface, that is, from the vertices of the projections toward the first spacer principal surface AS1 by a distance of about 1% or less of the thickness of the spacer 10, for example, are considered to be included in the flat surface of the second spacer principal surface AS2, and portions recessed to a depth of greater than about 1% of the thickness of the spacer 10 are defined as the recesses 11, for example.

The opening area of each recess 11 is preferably about 0.1% or more and about 70% or less of the surface area of the second spacer principal surface AS2, for example.

The reason for this is as follows. When the opening area of each recess 11 is greater than about 70% of the area of the second spacer principal surface AS2, for example, an excessive amount of solder 240 is trapped in the recesses 11, and the solder 240 cannot easily spread to the spacer end surfaces CS and the spacer side surfaces BS of the spacer 10. Therefore, there is a possibility that the joining strength between the spacer 10 and the mounting board 210 will be reduced. When the opening area of each recess 11 is less than about 0.1% of the area of the second spacer principal surface AS2, for example, the recesses 11 in the spacer 10 do not receive a sufficient amount of solder 240, and a sufficient anchoring effect cannot be provided.

The opening area of each recess 11 is more preferably about 0.5% or more and about 65% or less, still more preferably about 1% or more and about 60% or less, and particularly preferably about 5% or more and about 50% or less of the area of the second spacer principal surface AS2, for example.

The number of recesses 11 is selected as appropriate to satisfy the above-described conditions of the total opening area of the recesses 11 and the opening area of each recess 11.

The inner shapes of the recesses 11 are not particularly limited. For example, each recess 11 may have a pointed shape with the thickness decreasing from the second spacer principal surface AS2 toward the first spacer principal surface AS1, or a shape that is wider in the inside than at the opening.

The depth of each recess 11 is preferably about 1% or more and about 50% or less of the thickness of the spacer 10 in the lamination direction T, for example. The lamination direction T is the direction in which the dielectric layers 4 and the inner electrode layers 5 are laminated in the above-described multilayer ceramic capacitor 1A. In the spacer 10, the lamination direction T is the direction connecting the first spacer principal surface AS1 and the second spacer principal surface AS2.

The “depth” of each recess 11 is the distance from the opening to the bottom of the recess 11 in the lamination direction T.

The depth of each recess 11 is preferably about 1% or more of the thickness of the spacer 10 in the lamination direction T, for example, because when the depth of each recess 11 is less than about 18, the surface smoothness increases and the anchoring effect described below cannot be easily obtained.

The depth of each recess 11 is preferably about 50% or less of the thickness of the spacer 10 in the lamination direction T, for example, because when the depth of each recess 11 is greater than about 50%, the dimensions of portions of the spacer 10 in which the recesses 11 are provided in the lamination direction T are reduced, and therefore there is a possibility that the mechanical strength of the spacer 10 will be reduced.

In the present example embodiment, the recesses 11 include both the recesses 11 of about 1% or more and less than about 5% and the recesses 11 of about 5% or more, for example. The average depth of the recesses 11 of about 5% or more is more preferably about 5% or more and about 35% or less, still more preferably about 10% or more and about 20% or less, of the thickness of the spacer 10 in the lamination direction T, for example. The recesses 11 preferably include both the recesses 11 of about 1% or more and less than about 5% and the recesses 11 of about 5% or more, for example. The recesses 11 may include only the recesses 11 of about 1% or more and less than about 5%, or only the recesses 11 of about 5% or more, for example.

Preferably, the recesses 11 are also provided in the surfaces of the two spacer end surfaces CS of the spacer 10 that are opposite to each other in the length direction L. In addition, preferably, the recesses 11 are also provided in the surfaces of the two spacer side surfaces BS of the spacer 10 that are opposite to each other in the width direction W.

When the recesses 11 are provided also in the surfaces of the spacer end surfaces CS and the surfaces of the spacer side surfaces BS as described above, the solder 240 spreads upward along the surfaces of the spacer end surfaces CS and the spacer side surfaces BS, so that the fixing strength between the solder 240 and each outer electrode 3 can be increased.

However, as long as the recesses 11 are provided in the second spacer principal surface AS2 of the spacer 10, the recesses 11 need not be provided in the other surfaces. When the recesses 11 are provided in the other surfaces, the recesses 11 may be provided in one or more of the other surfaces instead of all of the other surfaces. The one or more of the other surfaces may be any surfaces.

For example, as long as the recesses 11 are provided in the second spacer principal surface AS2, the recesses 11 may be provided in one or both of the spacer side surfaces BS, and in one or both of the spacer end surfaces CS.

When the recesses 11 are provided in one of the other surfaces, the recesses 11 are preferably provided in the end surface CS1 of the first spacer 10A and the end surface CS2 of the second spacer 10B. The solder 240 that spreads upward along the first spacer end surface CS1 and the second spacer end surface CS2 can be received by the recesses 11 in the end surface CS1 of the first spacer 10A and the recesses 11 in the end surface CS2 of the second spacer 10B, and prevented from forming an excessive fillet or fillets. As long as the recesses 11 are provided in the second spacer principal surface AS2 of each spacer 10, the recesses 11 may be additionally provided in different surfaces of the first spacer 10A and the second spacer 10B.

The mounting board 210 on which the chip electronic component 1 is mounted is provided with lands 230. The lands 230 include a first land 230A and a second land 230B. The first spacer 10A and the second spacer 10B are respectively connected to the first land 230A and the second land 230B with the solder 240.

The recesses 11 are provided in the surface of the second spacer principal surface AS2, and these recesses 11 are filled with the solder 240. Therefore, the chip electronic component 1 and the mounting board 210 are joined with high fixing strength by the anchoring effect.

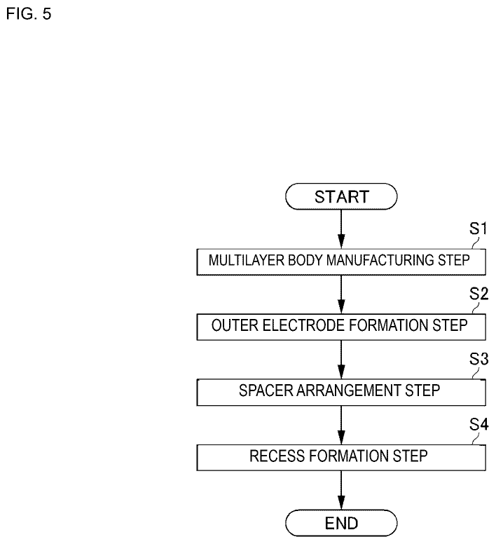

A non-limiting example of a method for manufacturing the chip electronic component 1 according to an example embodiment will now be described. FIG. 5 is a flowchart of the method for manufacturing the chip electronic component 1.

The manufacturing steps of the chip electronic component 1 include a multilayer body manufacturing step S1, an outer electrode formation step S2, a spacer arrangement step S3, and a recess formation step S4.

First, in the multilayer body manufacturing step S1, material sheets are prepared. The material sheets are obtained by printing patterns of the inner electrode layers 5 on lamination ceramic green sheets, which are obtained by molding a ceramic slurry into a sheet shape, with a conductor paste. The material sheets are stacked together such that the inner electrode patterns on adjacent ones of the material sheets are shifted from each other by one-half of the pitch in the length direction. Then, outer-layer-portion ceramic green sheets used to form the outer layer portions are stacked on both sides of the stack of material sheets, and are subjected to thermocompression bonding, so that a mother block is obtained. The mother block is divided along cutting lines set in accordance with the dimensions of the multilayer body, so that a plurality of multilayer bodies 2 are manufactured.

Next, in the outer electrode formation step S2, the outer electrodes 3 are formed on both end portions of the multilayer body 2. First, for example, the base electrode layers 30 are formed by applying the conductive paste including the conductive metal and glass to both end portions of the multilayer body 2 and baking the conductive paste. As illustrated in FIG. 2, the base electrode layers 30 are formed to extend not only over the capacitor end surfaces C at both ends of the multilayer body 2 but also along the capacitor principal surfaces A to cover portions of the capacitor principal surfaces A adjacent to the capacitor end surfaces C.

Then, first, the Ni plating layer 31a is provided on the outer periphery of each base electrode layer 30 to cover the base electrode layer 30. Then, the Sn plating layer 31b is provided on the outer periphery of the Ni plating layer 31a to cover the Ni plating layer 31a. Through the above-described steps, the multilayer ceramic capacitor 1A in which the outer electrodes 3 are formed on the multilayer body 2 is manufactured.

In the spacer arrangement step S3, an intermetallic compound paste, which is the material of the spacers 10, is applied to the outer peripheries of the outer electrodes 3 of the multilayer ceramic capacitor 1A at the side adjacent to the second capacitor principal surface A2.

The intermetallic compound paste is a so-called high-temperature solder containing an intermetallic compound as the main component, the intermetallic compound including at least one of Cu or Ni as a high-melting-point metal and Sn as a low-melting-point metal.

The intermetallic compound paste is temporarily melted at a temperature of 200° C. or above, and is applied to the surface of the Sn plating layer 31b in a liquid state.

The high-temperature solder has a melting point such that melting does not occur at an ordinary soldering temperature, and the desired shape thereof can be maintained during soldering.

Before the high-temperature solder solidifies, the intermetallic compound paste is brought into contact with, for example, an alumina plate at the second-principal-surface side. The alumina plate serves as a plate that has the desired projections and recesses and that is not joined to the high-temperature solder. After the intermetallic compound paste solidifies, the alumina plate is removed. Thus, the recesses 11 can be formed in the second spacer principal surface AS2 of each spacer 10.

The recesses 11 in the spacer end surfaces CS and the spacer side surfaces BS can be formed by placing the alumina plate such that the alumina plate extends along the end surfaces and the side surfaces.

The areas and depths of the recesses 11 can be adjusted by adjusting the areas, heights, and depths of the projections and recesses formed on the alumina plate.

The above-described method of bringing the alumina plate into contact is suitable for forming the recesses 11 having a depth of, for example, about 5% or more of the thickness of the spacers 10 in the lamination direction T. To form the recesses 11 having a depth of, for example, about 1% or more and less than about 5% of the thickness of the spacers 10 in the lamination direction T, sandblasting, for example, is suitable. However, any method may be used to form the recesses 11 irrespective of the depths of the recesses 11.

The method for forming the recesses 11 is not limited to the above-described methods, and other methods may be used. For example, after the intermetallic compound paste is solidified, the solidified surface may be roughened using a file or the like to form the recesses. Alternatively, the recesses may be formed by a chemical method, such as etching.

The chip electronic component 1 is manufactured by the above-described steps.

According to the chip electronic component 1 of the present example embodiment, the recesses 11 are provided in the surface of the second spacer principal surface AS2. Therefore, when the chip electronic component 1 is mounted on the mounting board 210, the solder 240 flows into the recesses 11 and exerts the anchoring effect that increases the fixing strength between the solder 240 and each spacer 10.

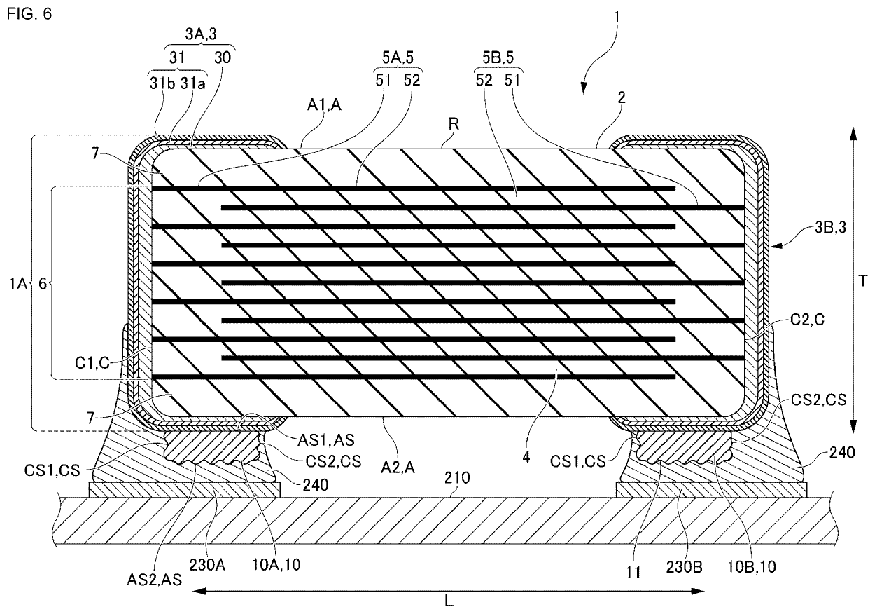

The solder 240 may cover both the spacers 10 and the side surfaces of the outer electrodes 3, as illustrated in FIG. 6, instead of being between each spacer 10 and the corresponding land 230 as illustrated in FIG. 2. Each spacer 10 of an example embodiment includes the recesses 11 provided in the surfaces of the spacer end surfaces CS and the surfaces of the spacer side surfaces BS. Therefore, when the solder 240 covers both the spacers 10 and the side surfaces of the outer electrodes 3 as illustrated in FIG. 6, the solder 240 flows into the recesses 11 in the surfaces of the spacer end surfaces CS and the surfaces of the spacer side surfaces BS. Therefore, the anchoring effect is enhanced, and the fixing strength between the solder 240 and each spacer 10 can be further increased.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A chip electronic component comprising:
a multilayer ceramic capacitor; and
spacers; wherein
the multilayer ceramic capacitor includes:
a multilayer body including a plurality of inner electrode layers and a plurality of inner dielectric layers that are alternately arranged; and
outer electrodes;
the multilayer body includes:
capacitor principal surfaces opposite to each other in a lamination direction;
capacitor side surfaces opposite to each other in a width direction that crosses the lamination direction; and
capacitor end surfaces opposite to each other in a length direction that crosses the lamination direction and the width direction; and
the outer electrodes are provided on respective ones of the capacitor end surfaces;
the spacers are provided at both ends of one of the capacitor principal surfaces in the length direction, the one of the capacitor principal surfaces being adjacent to a mounting board for the multilayer ceramic capacitor; and
each of the spacers includes spacer principal surfaces opposite to each other in the lamination direction, and at least one recess is provided in a surface of one of the spacer principal surfaces that is adjacent to the mounting board.

2. The chip electronic component according to claim 1, wherein of the each spacers includes an intermetallic compound including a high-melting-point metal and a low-melting-point metal as a main component.

3. The chip electronic component according to claim 2, wherein
the high-melting-point metal includes at least one of Cu or Ni; and
the low-melting-point metal includes Sn.

4. The chip electronic component according to claim 1, wherein each of the spacers includes a conductive resin.

5. The chip electronic component according to claim 1, wherein a total opening area of each of the at least one recess in each of the spacers is about 25% or more and about 75% or less of a surface area of the one of the spacer principal surfaces that is adjacent to the mounting board.

6. The chip electronic component according to claim 1, wherein an opening area of each of the at least one recess in each of the spacers is about 0.18 or more and about 70% or less of a surface area of the one of the spacer principal surfaces that is adjacent to the mounting board.

7. The chip electronic component according to claim 1, wherein a depth of each of the at least one recess in the lamination direction is about 1% or more and about 50% or less of a thickness of each of the spacers in the lamination direction.

8. The chip electronic component according to claim 1, wherein each of the spacers includes two spacer end surfaces that are opposite to each other in the length direction and include recesses in surfaces thereof.

9. The chip electronic component according to claim 1, wherein each of the spacers includes two spacer side surfaces that are opposite to each other in the width direction and include recesses in surfaces thereof.

10. The chip electronic component according to claim 1, wherein
in the multilayer body, one of the capacitor end surfaces is defined as a first capacitor end surface, another of the capacitor end surfaces is defined as a second capacitor end surface, and one of the capacitor principal surfaces that is adjacent to the spacers is defined as a second capacitor principal surface;
each of the spacers includes two spacer end surfaces that are opposite to each other in the length direction, a first of the two spacer end surfaces being defined as a first spacer end surface, and a second of the two spacer end surfaces being defined as a second spacer end surface;
the spacers include:
a first spacer in contact with a portion of a first outer electrode that is one of the outer electrodes adjacent to the first capacitor end surface, the portion of the first outer electrode extending along the second capacitor principal surface; and
a second spacer in contact with a portion of a second outer electrode that is one of the outer electrodes adjacent to the second capacitor end surface, the portion of the second outer electrode extending along the second capacitor principal surface;
at least one recess is provided in the first spacer end surface of the first spacer that is adjacent to the first capacitor end surface; and
at least one recess is provided in the second spacer end surface of the second spacer that is adjacent to the second capacitor end surface.

11. The chip electronic component according to claim 1, wherein each of the outer electrodes includes a base electrode layer and a plating layer.

12. The chip electronic component according to claim 1, wherein each of the spacers has a rectangular or substantially rectangular shape.

13. The chip electronic component according to claim 1, wherein the spacers have a same shape.

14. The chip electronic component according to claim 1, wherein the surface of the one of the spacer principal surfaces that is adjacent to the mounting board is a mounting surface joined to the mounting board.

15. The chip electronic component according to claim 4, wherein the conductive resin includes about 35 vol % or more and about 75 vol % or less of metal.

16. The chip electronic component according to claim 4, wherein the conductive resin includes metal particles with an average size of about 0.3 μm or more and about 10 μm or less.

17. The chip electronic component according to claim 4, wherein the conductive resin includes about 25 vol % or more and about 65 vol % or less of resin.

18. The chip electronic component according to claim 1, wherein at least one of the spacer principal surfaces includes projections and recesses.

19. The chip electronic component according to claim 1, wherein each of the at least one recess has a pointed shape with a decreasing thickness or a shape that is wider inside than at an opening.

20. The chip electronic component according to claim 1, wherein each of the at least one recess has a depth of about 18 to about 50% of a thickness of the respective spacer.
